(19) United States
(12) Patent Application Publication
(10) Pub. No.: US 2025/0390641 A1
(43) Pub. Date: Dec. 25, 2025

(54) DIAGNOSIS SYSTEM AND DIAGNOSIS METHOD

(71) Applicant: Mitsubishi Electric Corporation, Tokyo (JP)

(72) Inventors: Tetsushi ISHIDA, Tokyo (JP); Kenta HAMADA, Tokyo (JP)

(73) Assignee: Mitsubishi Electric Corporation, Tokyo (JP)

(21) Appl. No.: 19/120,803

(22) PCT Filed: Feb. 16, 2023
(86) PCT No.: PCT/JP2023/005407

§ 371 Date: Apr. 14, 2025

(51) Int. Cl. G06F 30/27

(52) U.S. Cl. CPC G06F 30/27

(57) ABSTRACT

A training device includes a simulation data acquirer that acquires first simulation data through machining simulation with a first machining program, an actual machining data acquirer that acquires first actual machining data through actual machining with the first machining program, and a model generator that learns a relationship between the first simulation data and the first actual machining data and generates a trained model for predicting, based on second simulation data acquired through machining simulation with a second machining program, second actual machining data acquired through actual machining with the second machining program.

### TECHNICAL FIELD

The present disclosure relates to a training device, a prediction device, a diagnosis device, a diagnosis system, a model generation method, a prediction method, a diagnosis method, and a program.

### BACKGROUND ART

In the field of machine tools, the positional relationship between a cutting tool attached to a machine tool and a workpiece (target object) is controlled based on a machining program to cut the workpiece into an intended shape with the cutting tool. In a cutting process, when the cutting tool does not have a predetermined shape (for example, the cutting tool that has greatly worn), a workpiece cannot be machined into an intended shape. To achieve intended machining, various attempts have recently been conducted to determine the machining states of machine tools.

As a technique related to these attempts, Patent Literature 1 describes a machining state diagnosis device that learns the relationship between estimated machining state information acquired by virtually machining a workpiece based on control information and actual machining state information acquired by actual machining based on the control information. The machining state diagnosis device can determine whether the machining state has an abnormality by comparing machining state information acquired by machining based on predetermined control information with actual machining state information derived from estimated machining state information estimated from the corresponding control information and the learned relationship.

### CITATION LIST

### Patent Literature

Patent Literature 1: Unexamined Japanese Patent Application Publication No. 2021-026598

### SUMMARY OF INVENTION

### Technical Problem

However, the machining state diagnosis device described in Patent Literature 1 learns the relationship between estimated machining state information and actual machining state information associated with multiple machining processes, such as straightening, grooving, drilling, and corner rounding, and has a large error between machining state information acquired by machining based on predetermined control information and actual machining state information derived from estimated machining state information estimated from the corresponding control information and the learned relationship. With such machining state information and actual machining state information having a large error compared to determine whether the machining state has an abnormality, the machining state diagnosis result is unreliable.

Under such circumstances, an objective of the present disclosure is to provide a diagnosis device that accurately estimates machining state information and reliably determines whether the machining state has an abnormality.

### Solution to Problem

To achieve the above objective, a training device according to an aspect of the present disclosure includes simulation data acquisition means for acquiring first simulation data through machining simulation with a first machining program, actual machining data acquisition means for acquiring first actual machining data through actual machining with the first machining program, and model generation means for learning a relationship between the first simulation data and the first actual machining data and generating a trained model for predicting, based on second simulation data acquired through machining simulation with a second machining program, second actual machining data acquired through actual machining with the second machining program.

### Advantageous Effects of Invention

The technique according to the above aspect of the present disclosure allows accurate prediction of actual machining data and reliable diagnosis of whether machining has an abnormality.

### BRIEF DESCRIPTION OF DRAWINGS

FIG. 1 is a diagram of a machining system according to Embodiment 1 of the present disclosure illustrating an overall configuration;

FIG. 2 is a functional block diagram of a training device according to Embodiment 1 of the present disclosure;

FIG. 3 is a functional block diagram of a prediction device according to Embodiment 1 of the present disclosure;

FIG. 4 is a functional block diagram of a diagnosis device according to Embodiment 1 of the present disclosure;

FIG. 5 is a functional block diagram of a terminal device in Embodiment 1 of the present disclosure;

FIG. 6 is a diagram of an example hardware configuration of the training device, the prediction device, the diagnosis device, and the terminal device according to Embodiment 1 of the present disclosure;

FIG. 7 is a flowchart of an example operation of generating a model performed by the training device according to Embodiment 1 of the present disclosure;

FIG. 8 is a flowchart of an example operation of predicting actual machining data performed by the prediction device according to Embodiment 1 of the present disclosure; and

FIG. 9 is a flowchart of an example operation of diagnosing abnormalities in a cutting tool performed by a diagnosis device according to Embodiment 2 of the present disclosure.

### DESCRIPTION OF EMBODIMENTS

Embodiments of a machining system including a training device, a prediction device, a diagnosis device, and a diagnosis system in an aspect of the present disclosure are described with reference to the drawings. Like reference signs denote like or corresponding components in the drawings.

### Embodiment 1

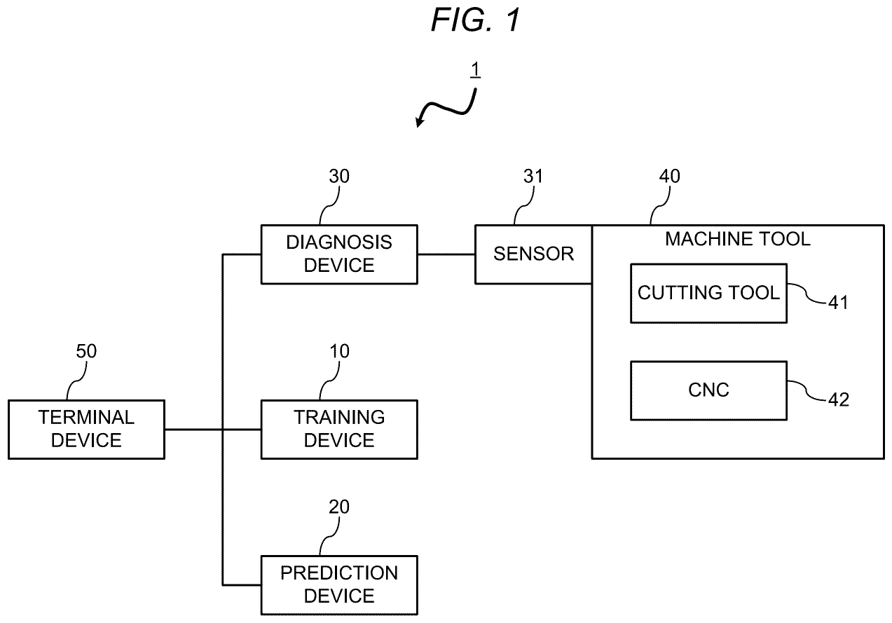

A machining system 1 according to Embodiment 1 is described with reference to FIG. 1.

The machining system 1 includes a training device 10, a prediction device 20, a diagnosis device 30, a sensor 31, a machine tool 40, a cutting tool 41, a computer numerical controller (CNC) 42, and a terminal device 50. The machining system 1 is, for example, installed at a production site in a factory.

As described later, the machining system 1 allows a machining simulation phase, an actual machining phase, a training phase, a prediction phase, and a diagnosis phase to be performed. The term actual machining is used to emphasize the difference from machining simulation referring to virtual machining.

The functions of each device are now described schematically. The details are described later.

The training device 10 generates a trained model for prediction of actual machining data in the prediction device 20 based on simulation data acquired by machining simulation with a machining program and actual machining data acquired by actual machining with the machining program. The simulation data is data acquired in time series during the machining simulation, such as an axis position, an axial cutting depth of the cutting tool, a radial cutting depth of the cutting tool, and a cutting volume. The actual machining data is data acquired in time series during the actual machining, such as an axis position and a torque spindle speed. The training device 10 is implemented by, for example, a personal computer or a server. The training device 10 is an example of a training device in an aspect of the present disclosure.

The prediction device 20 predicts the actual machining data based on the simulation data based on the trained model generated by the training device 10. The prediction device 20 is implemented by, for example, a personal computer or a server. The prediction device 20 is an example of a prediction device in an aspect of the present disclosure.

The diagnosis device 30 compares actual machining data acquired from the sensor 31 during actual machining with the actual machining data (prediction data) predicted by the prediction device 20 to determine whether the machining has an abnormality. The sensor 31 is a set of various sensors installed on the machine tool 40 to sense the state of the machine tool 40. The sensor 31 acquires time-series data during actual machining, such as an axis position and torque. The diagnosis device 30 is implemented by, for example, a programmable logic controller (PLC) or a personal computer. The diagnosis device 30 is an example of a diagnosis device in an aspect of the present disclosure.

The machine tool 40 operates based on the control of the CNC 42, and the positional relationship is controlled between the cutting tool 41 attached to a spindle included in the machine tool 40 and a workpiece (target object) fixed to a table or a turning spindle included in the machine tool 40. As the spindle or the turning spindle rotates, the cutting tool 41 or the workpiece rotates. When the cutting tool 41 comes in contact with the workpiece, the cutting tool 41 cuts a part of the workpiece.

The terminal device 50 is, for example, a personal computer for factory automation (FA). The user of the terminal device 50 is, for example, a worker in the factory. The terminal device 50 incorporates a computer-aided manufacturing (CAM) tool and generates a machining program for intended machining as operated by the user. The generated machining program is used to acquire simulation data from machining simulation or to acquire actual machining data from actual machining.

As described above, various data items are exchanged between multiple devices as appropriate. The data may be exchanged through communication between the devices or through removable media. For ease of illustration, each of the devices described below is connected as appropriate with a communication line illustrated in FIG. 1.

The above machining simulation phase, actual machining phase, training phase, prediction phase, and diagnosis phase are now described schematically.

### (1) Machining Simulation Phase

In the machining simulation phase, a machining program is input into the terminal device 50, and the terminal device 50 performs machining simulation with the input machining program to acquire simulation data. In the machining simulation, the shape of the workpiece is determined by controlling the positional relationship between the cutting tool and the workpiece in a virtual space based on control information acquired through the execution of the machining program and by removing the area of the workpiece through which the cutting tool passes. The simulation data is data acquired in time series during the machining simulation, such as an axis position, an axial cutting depth of the cutting tool, a radial cutting depth of the cutting tool, and a cutting volume. The simulation data is used for generating a trained model in the training phase (described later).

Although the machining process performed with the machining program includes multiple machining processes such as straightening, grooving, and drilling, the machining program often does not contain a description that identifies each machining process. In the machining simulation phase, each machining process is identified in the acquired simulation data to sort the simulation data for each machining process. More specifically, time-series changes in the simulation data are captured to sort the simulation data for each machining process. For example, a point at which the radial cutting depth of the cutting tool changes to a value near the cutting tool radius can be identified as a shift of the machining process to grooving. For example, a point at which the cutting tool is changed to a drill can be identified as a shift of the machining process to drilling. Information about the machining processes identified in the machining simulation phase is used in the actual machining phase (described later) to sort actual machining data for each machining process.

The machining program executed for machining simulation in the machining simulation phase differs from a machining program executed for prediction of actual machining data in the prediction phase (described later). For example, the machining program for machining simulation in the machining simulation phase is a machining program X, and the machining program for prediction of actual machining data in the prediction phase is a machining program Y. For clarity, the machining program in the machining simulation phase is hereafter referred to as a first machining program, and the simulation data as first simulation data.

### (2) Actual Machining Phase

In the actual machining phase, the first machining program is input into the machine tool 40, and the machine tool 40 performs actual machining. The diagnosis device 30 acquires data acquired from the sensor 31 during the actual machining as actual machining data. The actual machining data is data acquired in time series during the actual machining, such as an axis position and torque. The actual machining data is used to generate a trained model in the training phase (described later).

The information about the machining processes identified in (1) Machining Simulation Phase is used to sort the actual machining data for each machining process. More specifically, with the time-series phases of the simulation data and the actual machining data aligned, the actual machining data may be sorted for each machining process in the same manner as the simulation data. For clarity, the actual machining data acquired in the actual machining phase is hereafter referred to as first actual machining data.

In the actual machining phase, the cutting tool 41 in the machine tool 40 may have no deterioration. The first actual machining data acquired in the actual machining phase is used in the training phase (described later) to generate a trained model. With the cutting tool 41 that has deteriorated, the relationship between the first simulation data and the first actual machining data is learned based on the first actual machining data acquired by cutting with the deteriorated cutting tool, causing the determination of whether the machining has an abnormality to be unreliable.

### (3) Training Phase

In the training phase, the first simulation data acquired for each machining process in (1) Machining Simulation Phase and the first actual machining data acquired for each machining process in (2) Actual Machining Phase are input into the training device 10, and the training device 10 generates a trained model that associates the input first simulation data with the first actual machining data. The generated trained model is used in the prediction phase (described later) to predict actual machining data based on simulation data. This simulation data refers to simulation data not used to generate the trained model. The trained model can be used to predict actual machining data based on simulation data without actual machining.

To increase prediction accuracy in the prediction phase (described later), or more specifically, to generate a trained model for more accurate prediction, multiple sets of first simulation data and first actual machining data may be used for training.

### (4) Prediction Phase

In the prediction phase, the terminal device 50 performs machining simulation with a machining program different from the first machining program to acquire simulation data in the same manner as in (1) Machining Simulation Phase. For clarity, the machining program in the prediction phase is hereafter referred to as a second machining program, and the simulation data as second simulation data.

The second simulation data acquired for each machining process in the terminal device 50 and the trained model generated in (3) Training phase are input into the prediction device 20, and the prediction device 20 predicts actual machining data. The predicted actual machining data is used to determine whether the machining has an abnormality in the diagnosis phase (described later). For clarity, the actual machining data predicted in the prediction phase is hereafter referred to as second actual machining data (prediction data). Actual machining data acquired by actual machining with the second machining program in the diagnosis phase (described later) is referred to as second actual machining data.

### (5) Diagnosis Phase

In the diagnosis phase, the diagnosis device 30 acquires the second actual machining data through actual machining with the second machining program in the same manner as in (2) Actual Machining Phase. The diagnosis device 30 then acquires the second actual machining data (prediction data) predicted in (4) Prediction Phase. The diagnosis device 30 compares the second actual machining data with the second actual machining data (prediction data) to determine whether the machining has an abnormality.

Through phases (1) to (5) above, the machining system 1 according to Embodiment 1 allows the second actual machining data (prediction data) for each machining process to be predicted based on the second simulation data for each machining process without actual machining. The machining system 1 according to Embodiment 1 also allows the second actual machining data and the second actual machining data (prediction data) to be compared to determine whether the machining has an abnormality.

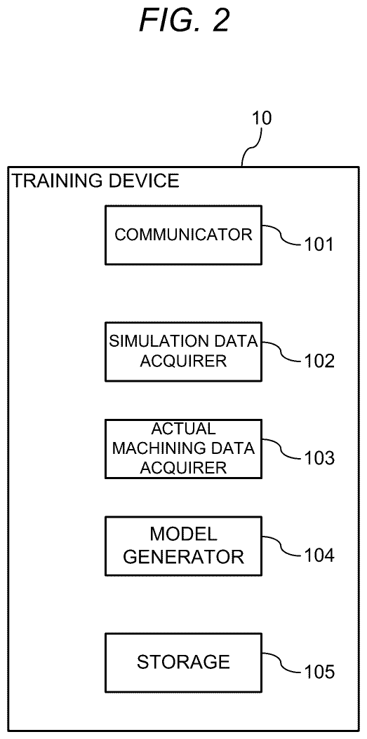

The functional components of the training device 10 are now described with reference to FIG. 2. The training device 10 includes a communicator 101, a simulation data acquirer 102, an actual machining data acquirer 103, a model generator 104, and a storage 105.

The communicator 101 communicates with external devices to transmit and receive various data items as appropriate. The communicator 101 is implemented by, for example, a network interface.

The simulation data acquirer 102 acquires the first simulation data for each machining process generated by the terminal device 50 in (1) Machining Simulation Phase. For example, the simulation data acquirer 102 communicates through the communicator 101 to acquire the first simulation data generated by the terminal device 50. The simulation data acquirer 102 is an example of simulation data acquisition means in an aspect of the present disclosure.

The actual machining data acquirer 103 acquires the first actual machining data for each machining process acquired by the diagnosis device 30 in (2) Actual Machining Phase. For example, the actual machining data acquirer 103 communicates through the communicator 101 to acquire the first actual machining data acquired by the diagnosis device 30. The actual machining data acquirer 103 is an example of actual machining data acquisition means in an aspect of the present disclosure.

The model generator 104 generates a trained model for prediction of the second actual machining data based on the second simulation data based on the first simulation data for each machining process acquired by the simulation data acquirer 102 and the first actual machining data for each machining process acquired by the actual machining data acquirer 103. The model generator 104 stores the generated trained model into the storage 105. For example, the model generator 104 uses a machine learning technique such as multiple regression analysis, support vector machines, random forests, or gradient boosting trees (decision trees) for the generation. The model generator 104 is an example of model generation means in an aspect of the present disclosure.

As described above, the model generator 104 generates a trained model based on the first simulation data for each machining process and the first actual machining data for each machining process. The generated trained model is thus optimized for each machining process. As described later, this enables actual machining data to be predicted accurately by predicting the second actual machining data (prediction data) for each machining process.

The storage 105 stores the trained model generated by the model generator 104. The storage 105 is an example of storage means in an aspect of the present disclosure.

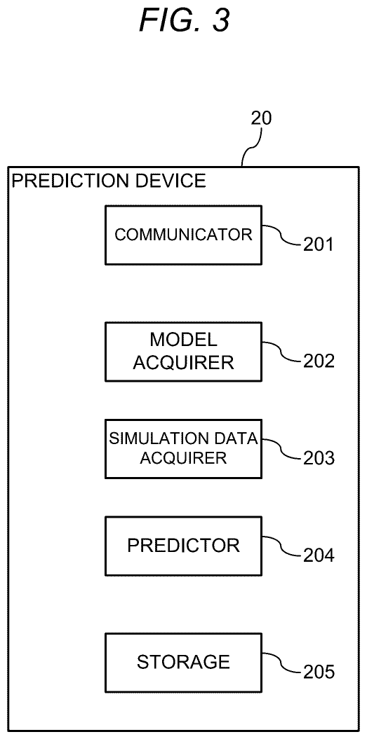

The functional components of the prediction device 20 are now described with reference to FIG. 3. The prediction device 20 includes a communicator 201, a model acquirer 202, a simulation data acquirer 203, a predictor 204, and a storage 205.

The communicator 201 communicates with external devices to transmit and receive various data items as appropriate. The communicator 201 is implemented by, for example, a network interface.

The model acquirer 202 acquires the trained model generated by the training device 10 in (3) Training phase and stores the trained model into the storage 205. For example, the model acquirer 202 acquires the trained model stored in the storage 105 in the training device 10 and stores the trained model into the storage 205 through the communicator 201.

The simulation data acquirer 203 acquires the second simulation data for each machining process generated by the terminal device 50 in (4) Prediction Phase. For example, the simulation data acquirer 203 communicates through the communicator 201 to acquire the second simulation data generated by the terminal device 50.

The predictor 204 refers to the trained model stored in the storage 205 and inputs the second simulation data for each machining process acquired by the simulation data acquirer 203 into the trained model to predict the second actual machining data (prediction data) for each machining process. The predictor 204 is an example of prediction means in an aspect of the present disclosure.

The storage 205 stores the trained model acquired by the model acquirer 202.

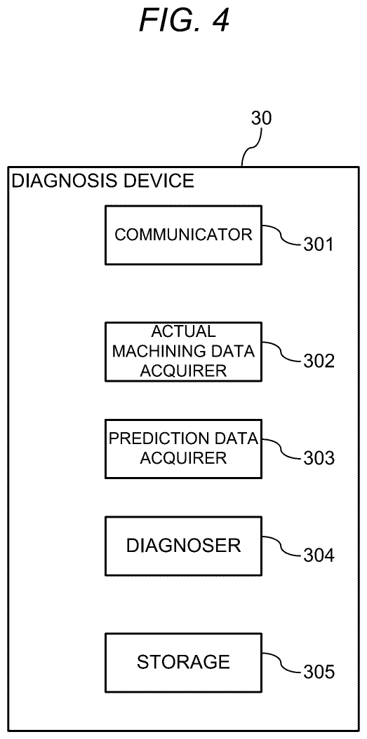

The functional components of the diagnosis device 30 are now described with reference to FIG. 4. The diagnosis device 30 includes a communicator 301, an actual machining data acquirer 302, a prediction data acquirer 303, a diagnoser 304, and a storage 305.

The communicator 301 communicates with external devices to transmit and receive various data items as appropriate. The communicator 301 is implemented by, for example, a network interface.

The actual machining data acquirer 302 acquires data from the sensor 31 through the communicator 301 as second actual machining data for each machining process. More specifically, the actual machining data acquirer 302 acquires data from the sensor 31 during actual machining by the machine tool 40 as second actual machining data for each machining process. The actual machining data acquirer 302 stores the acquired second actual machining data into the storage 305.

The prediction data acquirer 303 acquires the second actual machining data (prediction data) predicted by the prediction device 20. The prediction data acquirer 303 stores the second actual machining data (prediction data) into the storage 305. The prediction data acquirer 303 is an example of prediction data acquisition means in an aspect of the present disclosure.

The diagnoser 304 compares the second actual machining data acquired by the actual machining data acquirer 302 with the second actual machining data (prediction data) acquired by the prediction data acquirer 303 to determine whether the machining has an abnormality. The diagnoser 304 is an example of diagnosis means in an aspect of the present disclosure.

The storage 305 stores the second actual machining data for each machining process acquired by the actual machining data acquirer 302 and the second actual machining data (prediction data) acquired by the prediction data acquirer 303.

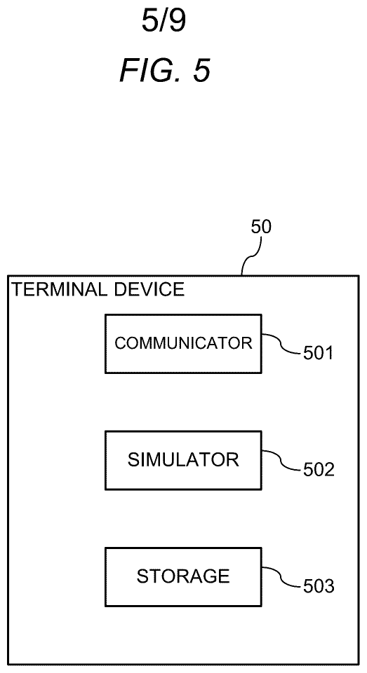

The functional components of the terminal device 50 are now described with reference to FIG. 5. The terminal device 50 includes a communicator 501, a simulator 502, and a storage 503.

The communicator 501 communicates with external devices to transmit and receive various data items as appropriate. The communicator 501 is implemented by, for example, a network interface.

A machining program is input into the simulator 502 and the simulator 502 performs machining simulation with the input machining program to acquire simulation data. The simulator 502 stores the acquired simulation data into the storage 503.

The storage 503 stores the simulation data for each machining process acquired by the simulator 502.

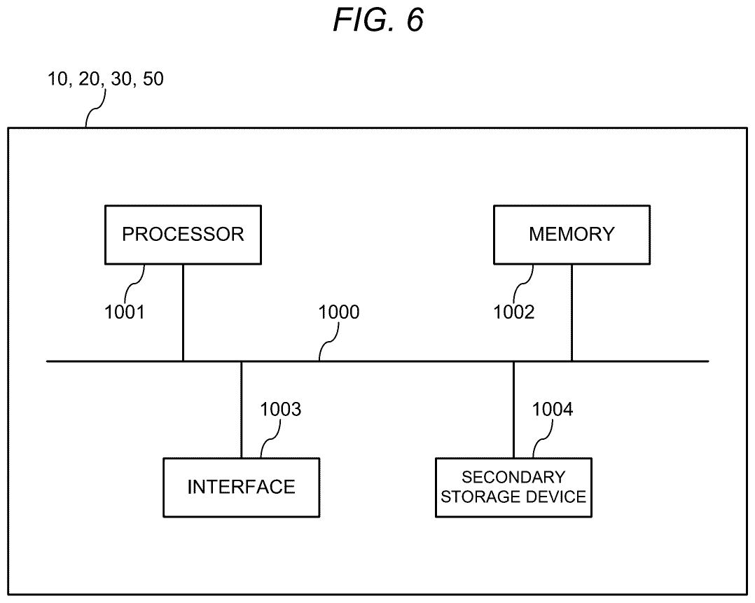

An example hardware configuration of the training device 10, the prediction device 20, the diagnosis device 30, and the terminal device 50 (hereafter referred to as the training device 10 and other devices) is now described with reference to FIG. 6. The training device 10 and other devices illustrated in FIG. 6 are implemented by, for example, computers such as a personal computer, a microcontroller, and a PLC.

Each of the training device 10 and other devices includes a processor 1001, a memory 1002, an interface 1003, and a secondary storage device 1004 that are connected to each other with a bus 1000.

The processor 1001 is, for example, a central processing unit (CPU). The processor 1001 loads the operating program stored in the secondary storage device 1004 into the memory 1002 and executes the operating program to implement the functions of each of the training device 10 and other devices.

The memory 1002 is a main storage device including, for example, a random-access memory (RAM). The memory 1002 stores the operating program loaded by the processor 1001 from the secondary storage device 1004. The memory 1002 serves as a work memory when the processor 1001 executes the operating program.

The interface 1003 is an input-output (I/O) interface, such as a serial port, a universal serial bus (USB) port, or a network interface. The interface 1003 implements the functions of the communicator 101, the communicator 201, the communicator 301, and the communicator 501.

The secondary storage device 1004 is, for example, a flash memory, a hard disk drive (HDD), or a solid-state drive (SSD). The secondary storage device 1004 stores the operating program to be executed by the processor 1001. The secondary storage device 1004 implements the functions of the storage 105, the storage 205, the storage 305, and the storage 503.

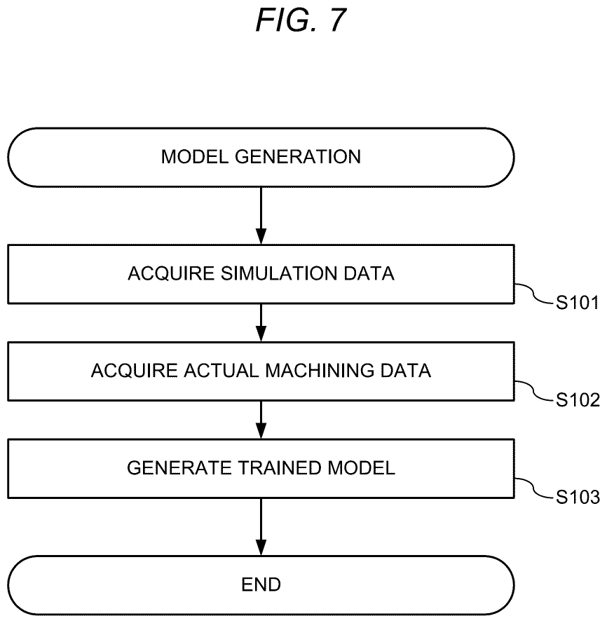

An example operation of generating a model performed by the training device 10 is now described with reference to FIG. 7. The operation illustrated in FIG. 7 is performed when, for example, the user operates and instructs the training device 10 to generate a training model. Before the operation illustrated in FIG. 7 is started, (1) Machining Simulation Phase and (2) Actual Machining Phase are already performed.

The simulation data acquirer 102 in the training device 10 acquires first simulation data for each machining process (step S101).

The actual machining data acquirer 103 in the training device 10 then acquires first actual machining data for each machining process (step S102).

The model generator 104 in the training device 10 generates a trained model based on the first simulation data acquired in step S101 and the first actual machining data acquired in step S102 and stores the trained model into the storage 105 (step S103). The training device 10 then ends the operation of generating a model.

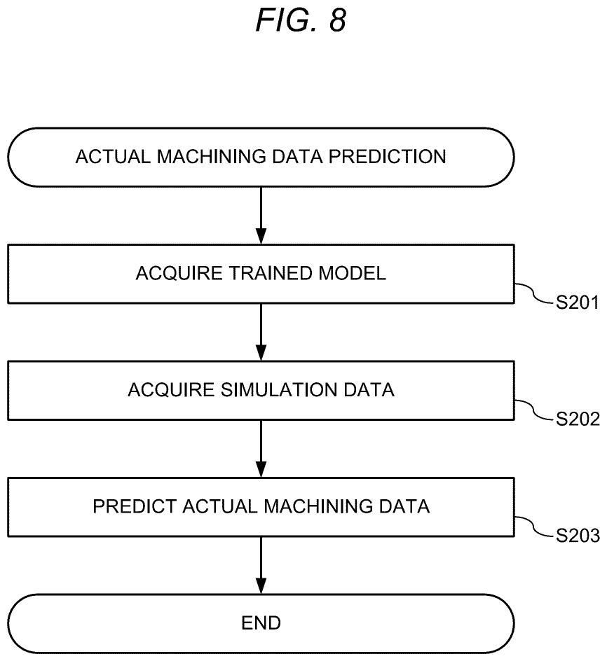

An example operation of predicting actual machining data performed by the prediction device 20 is now described with reference to FIG. 8. The operation illustrated in FIG. 8 is performed when, for example, the user operates and instructs the prediction device 20 to predict actual machining data. Before the operation illustrated in FIG. 8 is started, (3) Training phase is already performed to generate a trained model.

The model acquirer 202 in the prediction device 20 acquires and stores the trained model into the storage 205 (step S201). However, this operation may not be performed when, for example, the latest trained model is already stored in the storage 205.

The simulation data acquirer 203 in the prediction device 20 acquires second simulation data for each machining process (step S202).

The predictor 204 in the prediction device 20 refers to the trained model in the storage 205 stored in step S201 and predicts second actual machining data (prediction data) for each machining process based on the second simulation data for each machining process acquired in step S202 (step S203). The prediction device 20 then ends the operation of predicting actual machining data.

The machining system 1 according to Embodiment 1 is described above. The machining system 1 according to Embodiment 1 allows a trained model to be generated based on the first simulation data for each machining process acquired through machining simulation with the first machining program and the first actual machining data for each machining process acquired through actual machining with the first machining program, and reference to the trained model allows the second actual machining data (prediction data) for each machining process to be predicted without actual machining based on the second simulation data for each machining process acquired through machining simulation with the second machining program.

The machining system 1 according to Embodiment 1 also allows the second actual machining data (prediction data) for each machining process to be predicted using the trained model generated based on the first simulation data for each machining process and the first actual machining data for each machining process. The diagnosis device 30 thus can compare the second actual machining data for each machining process with the second actual machining data (prediction data) to determine whether the machining has an abnormality.

### Embodiment 2

In Embodiment 2, as described below, the actual machining data (prediction data) predicted in Embodiment 1 is used for abnormality diagnosis on the cutting tool.

Multiple actual machining operations of the machine tool wear the cutting tool included in the machine tool. Techniques are thus awaited for determining whether the cutting tool has an abnormality based on the actual machining state. For example, the cutting tool may be determined based on the sensor values detected by the sensors for the machine tool during actual machining.

When the machine tool produces mass-produced products, each operation of actual machining has the same machining conditions. Thus, the generation of a trained model associating, for example, the sensor values with abnormality status allows abnormality diagnosis on the cutting tool based on the trained model and the sensor values.

However, when the machine tool produces one-off products rather than mass-produced products, the machining shape and the machining process differ for each actual machining operation. Thus, a trained model used for abnormality diagnosis on a cutting tool for producing one-off products cannot be generated from multiple sets of the same machining data, unlike the trained model used for mass-produced products described above.

In Embodiment 2, the cutting tool undergoes abnormality diagnosis based on actual machining data acquired during actual machining and actual machining data (prediction data) predicted based on simulation data acquired through machining simulation with a machining program.

A machining system 1 according to Embodiment 2 has an overall configuration similar to the configuration in Embodiment 1 illustrated in FIG. 1. However, as described below, the diagnosis device 30 has some different functions. In Embodiment 2, (1) Machining Simulation Phase, (2) Actual Machining Phase, and (3) Training phase are performed before the cutting tool 41 deteriorates. The machining system 1 according to Embodiment 2 is an example of a diagnosis system in an aspect of the present disclosure.

In Embodiment 2, the diagnosis device 30 determines whether the cutting tool 41 in the machine tool 40 has an abnormality based on second actual machining data acquired by the sensor 31 and second actual machining data (prediction data) predicted by the prediction device 20. The diagnosis device 30 according to Embodiment 2 is an example of a diagnosis device in an aspect of the present disclosure.

The functional components of the diagnosis device 30 in Embodiment 2 are described focusing on the differences from the functional components in Embodiment 1.

The diagnoser 304 determines whether the cutting tool 41 has an abnormality based on features of the second actual machining data acquired by the actual machining data acquirer 302 and features of the second actual machining data (prediction data) acquired by the prediction data acquirer 303. The diagnoser 304 is an example of diagnosis means in an aspect of the present disclosure.

Examples of the features include the mean, variance, maximum/minimum, median, skewness, and convexity of the torque during actual machining. In a simple example, the diagnoser 304 may determine that the cutting tool 41 has an abnormality when the difference between the mean torque in the prediction data and the mean torque in the actual machining data is greater than or equal to a threshold. For example, the cutting tool 41 may have known characteristics and deteriorate to cause the torque to increase. In such an example, when the mean torque in the actual machining data is much greater than the mean torque in the prediction data, the cutting tool 41 may have an abnormality. Machining processes may cause the feature gap between the prediction data and the actual machining data to exceed or fall below a threshold.

More complex examples are described below. For example, an approximate curve may be determined for the distribution of time-varying features of second actual machining data and second actual machining data (prediction data) when the horizontal axis is elapsed time and the vertical axis is the difference between the features of the second actual machining data and the features of the second actual machining data (prediction data). Based on the approximate curve, the cutting tool 41 may undergo abnormality determination. This approximate curve herein includes a straight line, such as a regression line.

For example, with a regression line determined as an approximate curve, the slope of the regression line increases as the difference increases between the features of the second actual machining data and the features of the second actual machining data (prediction data). The cutting tool 41 may thus be determined to have an abnormality when the slope of the regression line becomes greater than or equal to a threshold. More specifically, as the slope of the regression line increases, the gap between the second actual machining data and the second actual machining data (prediction data) widens, or in other words, the cutting tool 41 has deteriorated.

In other examples, with an approximate curve determined by curve fitting, the cutting tool 41 may be determined to have an abnormality when an inflection point appears on the determined approximate curve. The inflection point is a point at which the rate of change in feature difference reverses from positive to negative or negative to positive and thus a point at which the tendency of feature difference changes greatly. Such a large change does not seem to occur without a deterioration in the cutting tool 41, and thus the appearance of an inflection point suggests that the cutting tool 41 has deteriorated.

The diagnoser 304 determines whether the cutting tool 41 has an abnormality and reports the diagnosis result. The diagnoser 304 outputs the diagnosis result to, for example, a display or an alarm (not illustrated) connected to the diagnosis device 30 as an alarm sound or a message. The diagnosis result is reported by displaying a message on the screen of the CNC 42 in the machine tool 40, outputting an alarm sound, or suspending new machining performed with the cutting tool 41.

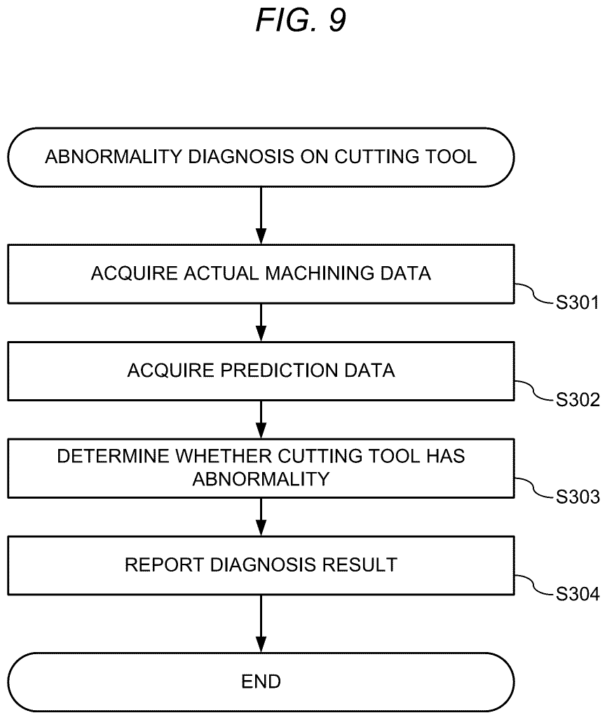

An example operation of diagnosing abnormalities in a cutting tool performed by the diagnosis device 30 is now described with reference to FIG. 9. The operation illustrated in FIG. 9 is performed when actual machining is performed after the execution of phases (1) to (4).

The actual machining data acquirer 302 in the diagnosis device 30 acquires second actual machining data from the sensor 31 (step S301).

The prediction data acquirer 303 in the diagnosis device 30 acquires second actual machining data (prediction data) predicted by the prediction device 20 (step S302).

The diagnoser 304 in the diagnosis device 30 determines whether the cutting tool 41 has an abnormality based on features of the second actual machining data acquired in step S301 and features of the second actual machining data (prediction data) acquired in step S302 (step S303).

The diagnoser 304 reports the diagnosis result of step S303 (step S304). The diagnosis device 30 then ends the operation of diagnosing abnormalities in a cutting tool.

The machining system 1 according to Embodiment 2 is described above.

The machining system 1 according to Embodiment 2 allows determination of whether the cutting tool 41 has an abnormality based on the features of the second actual machining data and the features of the second actual machining data (prediction data) predicted based on the second simulation data. The second actual machining data and the second actual machining data (prediction data) are data sorted for each machining process, thus enabling appropriate determination of whether the cutting tool 41 has an abnormality when the machine tool 40 machines a workpiece that is not a mass-produced product.

### Modifications

Although the diagnosis device 30 performs abnormality diagnosis on the cutting tool 41 in Embodiment 2, a device different from the diagnosis device 30 may perform abnormality diagnosis. For example, the diagnosis device 30 may output the second actual machining data to a personal computer, and the personal computer may acquire the second actual machining data and second actual machining data (prediction data) to perform abnormality diagnosis on the cutting tool 41. In this case, the personal computer has functions corresponding to the actual machining data acquirer 302, the prediction data acquirer 303, and the diagnoser 304 illustrated in FIG. 4. The personal computer is an example of a diagnosis device in an aspect of the present disclosure.

In each embodiment, the training device 10, the prediction device 20, the diagnosis device 30, and the terminal device 50 are separate devices. However, the functions of two or more of the devices may be combined in a single device. For example, with the functions of each device incorporated in a server, a personal computer, or the CNC 42 in the device 40, various items of intended data may be exchanged through communication through a network or a CPU bus.

In the hardware configuration illustrated in FIG. 6, each of the training device 10 and other devices includes the secondary storage device 1004. However, the secondary storage device 1004 may be external to each of the training device 10 and other devices, and each of the training device 10 and other devices may be connected to the secondary storage device 1004 through the interface 1003. In this configuration, the secondary storage device 1004 may be a removable medium such as a USB flash drive or a memory card.

In place of the hardware configuration illustrated in FIG. 6, a dedicated circuit using, for example, an application-specific integrated circuit (ASIC) or a field-programmable gate array (FPGA), may be included in each of the training device 10 and other devices. In the hardware configuration illustrated in FIG. 6, some of the functions of each of the training device 10 and other devices may be implemented by, for example, a dedicated circuit connected to the interface 1003.

The programs used by each of the training device 10 and other devices may be stored in a non-transitory computer-readable recording medium, such as a compact disc read-only memory (CD-ROM), a digital versatile disc (DVD), a USB flash drive, a memory card, or an HDD, and may then be distributed. The programs may be installed on a specific computer or a general-purpose computer, and the computer can then function as each of the training device 10 and other devices.

The programs may be stored in a storage device in another server on the Internet and may be downloaded from the server.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

### REFERENCE SIGNS LIST

1 Machining system
10 Training device
20 Prediction device
30 Diagnosis device
31 Sensor
40 Machine tool
41 Cutting tool
42 CNC
50 Terminal device
101 Communicator
102 Simulation data acquirer
103 Actual machining data acquirer
104 Model generator
105 Storage
201 Communicator
202 Model acquirer
203 Simulation data acquirer
204 Predictor
205 Storage
301 Communicator
302 Actual machining data acquirer
303 Prediction data acquirer
304 Diagnoser
305 Storage
501 Communicator
502 Simulator
503 Storage
1000 Bus
1001 Processor
1002 Memory
1003 Interface
1004 Secondary storage device

1.-5. (canceled)

6. A diagnosis system, comprising:
a prediction device; and
a diagnosis device, wherein
the prediction device comprises
a storage to store a trained model generated by a training device,
a simulation data acquirer to acquire second simulation data through machining simulation with a second machining program, and
a predictor to predict second actual machining data based on the trained model and the second simulation data,
the diagnosis device comprises
an actual machining data acquirer to acquire the second actual machining data through actual machining with the second machining program,
a prediction data acquirer to acquire prediction data for the second actual machining data predicted by the prediction device, and
a diagnoser to determine whether machining has an abnormality based on a feature of the second actual machining data and a feature of the prediction data for the second actual machining data, to determine an approximate curve for the feature of the second actual machining data and the feature of the prediction data for the second actual machining data, and to determine whether a cutting tool has an abnormality based on the determined approximate curve,
the trained model is a trained model that is generated by the training device, is acquired through learning a relationship between a first simulation data and a first actual machining data, and is for predicting, based on the second simulation data, the second actual machining data,
the first simulation data is acquired through machining simulation with a first machining program by the training device, and
the first actual machining data is acquired through actual machining with the first machining program by the training device.

7.-9. (canceled)

10. A diagnosis method to be implemented by one or more computers, the diagnosis method comprising:
acquiring second simulation data through machining simulation with a second machining program;
predicting, based on a trained model generated by a training device and the second simulation data, second actual machining data;
acquiring the second actual machining data through actual machining with the second machining program;
determining whether machining has an abnormality based on a feature of the second actual machining data and a feature of prediction data for the second actual machining data; and
determining an approximate curve for the feature of the second actual machining data and the feature of the prediction data for the second actual machining data and determining whether a cutting tool has an abnormality based on the determined approximate curve, wherein
the trained model is a trained model that is acquired through learning a relationship between a first simulation data and a first actual machining data and is for predicting, based on the second simulation data, the second actual machining data,
the first simulation data is acquired through machining simulation with a first machining program, and
the first actual machining data is acquired through actual machining with the first machining program.

11.-16. (canceled)
